(19) United States
(12) Patent Application Publication
(10) Pub. No.: US 2026/0079544 A1
(43) Pub. Date: Mar. 19, 2026

(54) HYBRID MODULAR ENCLOSURE FOR MULTIPLE MOBILE ELECTRONIC DEVICES AND ACCESSORIES WITH VARIABLE OPACITY, CUSTOMIZABLE SURFACES, EXTENSIBLE FEATURES, PARTIAL ACCESS CAPABILITIES, AND HYGIENIC CLEANABILITY

(71) Applicant: John Nguyen, Lake Elsinore, CA (US)

(72) Inventor: John Nguyen, Lake Elsinore, CA (US)

(21) Appl. No.: 19/398,047

(22) Filed: Nov. 24, 2025

(51) Int. Cl. G06F 1/18; G06F 1/16; H05K 5/00; H05K 5/02; H05K 9/00

(52) U.S. Cl. CPC G06F 1/182; G06F 1/1628; G06F 1/1635; G06F 1/1658; H05K 5/0086; H05K 5/0243; H05K 5/0252; H05K 9/0043

(57) ABSTRACT

A hybrid modular enclosure for mobile electronic devices reduces distractions while allowing partial access. The enclosure features a durable molded plastic frame with fabric panels, extended fabric extensions attached via glue or sewing for temporarily holding a tag-and-pin retainer to prevent content removal, and surfaces optimized for stickers and engraving such as school logos. Variable opacity (clear, semi-opaque, or opaque) is integrated into molded enclosure parts for customizable visibility. Modular points allow add-on components like added-function tags. Holes enable charging or limited interactions. The chamber holds multiple devices, smartwatches, earbuds, or wrapped phones. Molded plastic is non-porous for easy cleaning with solutions/wipes, addressing hygiene in shared use post-COVID and for future pathogens.

### CROSS-REFERENCE TO RELATED APPLICATIONS

Not Applicable

### STATEMENT REGARDING FEDERALLY SPONSORED RESEARCH OR DEVELOPMENT

Not Applicable

### BACKGROUND OF THE INVENTION

### Field of the Invention

The present invention relates to enclosures for mobile electronic devices, particularly those designed to reduce distractions in controlled environments such as educational settings, events, or workplaces, while allowing partial access to device functions.

### Description of Related Art

Mobile electronic devices, such as smartphones and tablets, have become ubiquitous, providing valuable tools for communication, information access, and productivity. However, in certain environments like schools or performances, these devices can cause significant distractions through notifications, social media, or unauthorized recordings.

Prior solutions, such as fabric-based pouches with dividing mechanisms (e.g., as described in U.S. Pat. No. 10,980,324), effectively conceal screens and limit full access while permitting emergency interactions via openings for ports or buttons.

Yondr's patent family (U.S. Pat. Nos. 9,819,788; 10,623,957; 12,133,078) discloses a shell with mateable panels and a locking means reliant on RFID/microprocessors for automatic locking and disengagement under geographic or temporal conditions. Claim 1 of U.S. Pat. No. 9,819,788, Claim 1 of U.S. Pat. No. 10,623,957, and Claim 1 of U.S. Pat. No. 12,133,078 emphasize locking until “physical presence outside a defined geographical region.”

Prosecution history for application Ser. No. 14/692,530 (amendment remarks dated Apr. 21, 2015) argues patentability over Stewart (US 2012/0187003) via distinctions in user-retained distraction control and no motivation to combine prior art, citing Graham v. John Deere Co. for obviousness standards.

However, these systems exhibit technical limitations: condition-dependent unlocking lacks user autonomy; single-device focus without multi-item capacity or wrapped shielding; no apertures for charging/limited interactions; uniform obscuration without variable opacity; non-modular locks requiring specialized key; and prosecution emphasis on non-obviousness constrains scope to integrated, non-extensible designs.

Litigation challenges assert invalidity under 35 U.S.C. § 101 as abstract ideas, comparing to age-old locking/unlocking concepts under Alice Corp. v. CLS Bank Int'l, and under 35 U.S.C. § 112 for indefiniteness, including lack of antecedent basis for “the predetermined condition” and failure to define locking means.

While Yondr's patents were granted, this does not guarantee validity or enforceability, as noted by examiners in rejections and ongoing litigation/IPR proceedings questioning specification support for structures/functions and abstractness.

Despite these advancements, existing enclosures often lack durability in high-use scenarios, such as repeated handling by students, leading to wear and tear. Materials may not support easy customization, such as applying school logos or identifiers, which could enhance institutional adoption and user compliance.

Additionally, uniform opacity limits flexibility; for instance, opaque designs prevent quick visual checks for device status, while fully transparent ones may not sufficiently reduce visual distractions.

There is also a need for more modular retainer systems that allow temporary, tool-free attachment and replacement of securing components, improving maintenance and adaptability.

Furthermore, current designs lack extensibility for add-on functionalities, such as integrating signal-blocking materials for selective RF shielding or other specialty modules (e.g., ventilation or multi-device separators), which could provide tailored enhancements without redesigning the core enclosure.

Moreover, prior art often overlooks dedicated holes for charging or limited interactions (e.g., accessing power buttons or volume controls), which are essential for practical use without full device removal.

Existing enclosures also typically do not accommodate multiple items (e.g., one or more mobile devices, smartwatches, or earbuds) or allow for a phone to be wrapped in a signal-blocking pouch within the chamber for added shielding.

The present invention addresses these shortcomings by introducing hybrid molded-fabric constructions, variable opacity options, sticker-compatible surfaces, extended fabric extensions for temporary retainer holds, modular attachment points for add-on components like signal-blocking pouches, holes for charging or limited access, and sufficient sizing to hold multiple devices/accessories with support for wrapped signal-blocking configurations.

### BRIEF SUMMARY OF THE INVENTION

The present invention provides an improved enclosure for mobile electronic devices, building upon prior fabric-based designs by incorporating hybrid molded plastic and fabric constructions for enhanced durability and customization.

The enclosure comprises a molded plastic frame forming a chamber, fabric panels attached to the frame, and a modular retainer system. The molded plastic components include smooth, sticker-adherent surfaces for applying custom logos, identifiers, or motivational graphics, facilitating branding in educational or organizational settings.

The fabric panels may comprise neoprene, vinyl, nylon, polyester, or combinations thereof, and include extended fabric parts attached via glue or sewing that serve as temporary holders for the retainer assembly, enabling easy attachment, removal, and replacement of locking parts without tools.

The enclosure features a semi-open chamber that prevents full removal of the device while allowing partial access to functions such as ports, buttons, or emergency notifications through one or more openings or apertures.

Variable opacity options—clear for monitoring, semi-opaque for partial visibility, or fully opaque for maximum distraction reduction—are integrated into panels or layers of the molded enclosure parts, providing adaptability to different use cases.

Additionally, the enclosure is modular, allowing attachment of add-on components such as signal-blocking material pouches for selective RF shielding or other specialty modules via clips, slots, or added interfaces, enhancing functionality without compromising the core design.

The enclosure may further include holes or apertures for charging access or limited interactions, such as connecting cables or pressing buttons, without breaching security.

The chamber is sized to hold at least one or more mobile devices, along with accessories like smartwatches and earbuds, and accommodates configurations where a phone is wrapped in a signal-blocking pouch for added shielding.

The molded plastic is non-porous and smooth for easy cleaning with disinfectant solutions or wipes, addressing hygiene needs in shared use by students or multiple users, particularly in post-COVID contexts to mitigate bacteria and virus risks.

Advantages include increased longevity, user compliance through personalization, simplified maintenance, extensible features, practical access, versatile storage, and hygienic cleanability, making the enclosure suitable for schools, events, and workplaces.

### BRIEF DESCRIPTION OF THE DRAWINGS

FIG. 1 is a perspective view of the hybrid enclosure in an assembled state, showing the molded plastic frame with at least one mobile devices and accessories housed inside and cleanable surface, fabric sides extended with retainer in place, holes for charging or limited access, and capacity for multiple devices or wrapped configurations.

FIG. 2 is a perspective view illustrating the molded plastic frame with non-porous surfaces.

FIG. 3 is a top view highlighting smooth surface with a personalized sticker.

FIG. 4 is a top view showing a molded frame with apertures and holes for charging cables and partial access to ports and buttons.

FIG. 5 is a exploded view showing a molded frame attached to extended fabric panels with retainer assembly parts positioned, temporarily holding the tag-and-pin retainer assembly.

FIG. 6 is a cross-sectional detail view of the extended fabric parts temporarily holding the tag-and-pin retainer assembly.

FIG. 7 is a detailed view of the tag-and-pin retainer assembly components.

FIG. 8 is a diagram view showing a chart of level of opacity of interchangeable molded frames with different opacity levels: clear, semi-opaque, and fully opaque.

FIG. 9 is a perspective view of the molded plastic chamber component showing internal space, attachment points, smooth surfaces on all sides ready to personalize with stickers or engraving.

FIG. 10 is a perspective view showing an mobile electronic device wrapped in shielding pouch or fabric and earbud case.

### DETAILED DESCRIPTION OF THE INVENTION

The detailed description set forth below, in connection with the appended drawings, is intended as a description of various embodiments of the disclosed subject matter and is not intended to represent only the embodiments. Each embodiment described in this disclosure is provided merely as an example or illustration and should not be construed as preferred or advantageous over other embodiments. The illustrative examples provided herein are not intended to be exhaustive or to limit the disclosure to the precise forms disclosed.

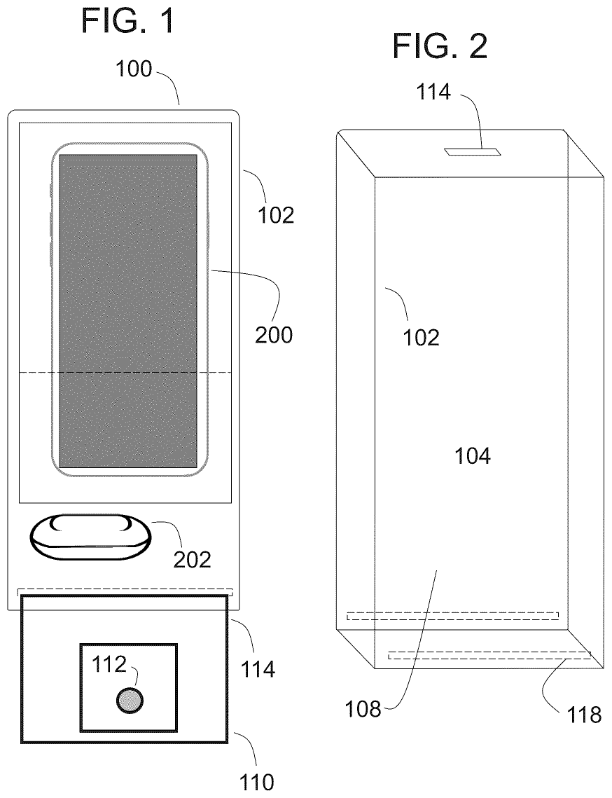

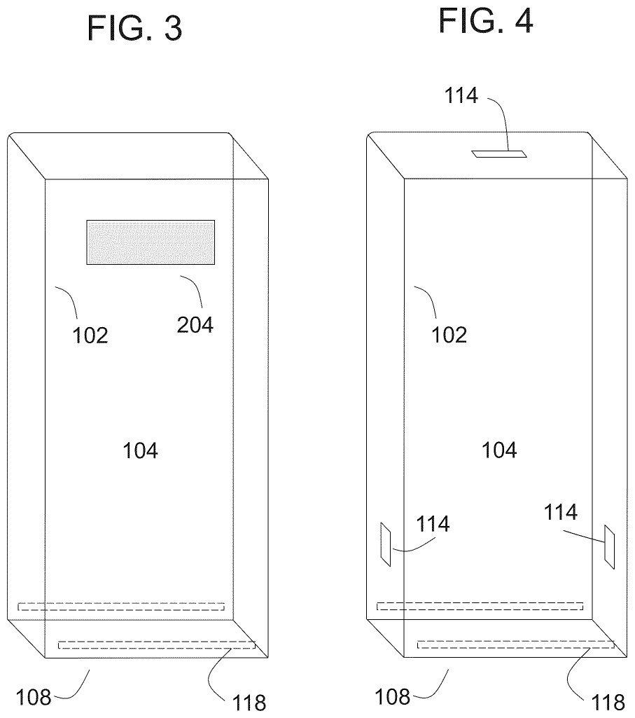

Referring to FIG. 1, the hybrid enclosure 100 comprises a molded plastic frame 102 providing structural rigidity and impact resistance. The frame 102 may be formed from polycarbonate, ABS, or similar durable materials. The frame 102 includes flat exterior surfaces 104 optimized for adhesive stickers, such as school logos or identifiers 204 (shown in FIGS. 1 and 3), with a smooth or textured finish to ensure secure attachment and easy removal without residue.

The molded plastic frame 102 is non-porous and resistant to cleaning solutions or wipes, facilitating hygiene maintenance in shared use. This feature is particularly important in educational settings where multiple students may handle the same enclosures, addressing concerns about bacteria and virus transmission, including COVID-19 and potential future pathogens.

Attached to the molded plastic frame 102 are fabric panels 110 that form a chamber 108 for receiving one or more mobile electronic devices. The fabric panels 110 may comprise neoprene, vinyl, nylon, polyester, or combinations thereof, selected for durability and flexibility.

As shown in FIGS. 1 and 2, the molded plastic frame 102 includes a structure 118 configured to attach or integrate the fabric panels 110 via glue, sewing, or other bonding methods. This hybrid construction combines the rigidity and cleanability of molded plastic with the flexibility and durability of fabric materials.

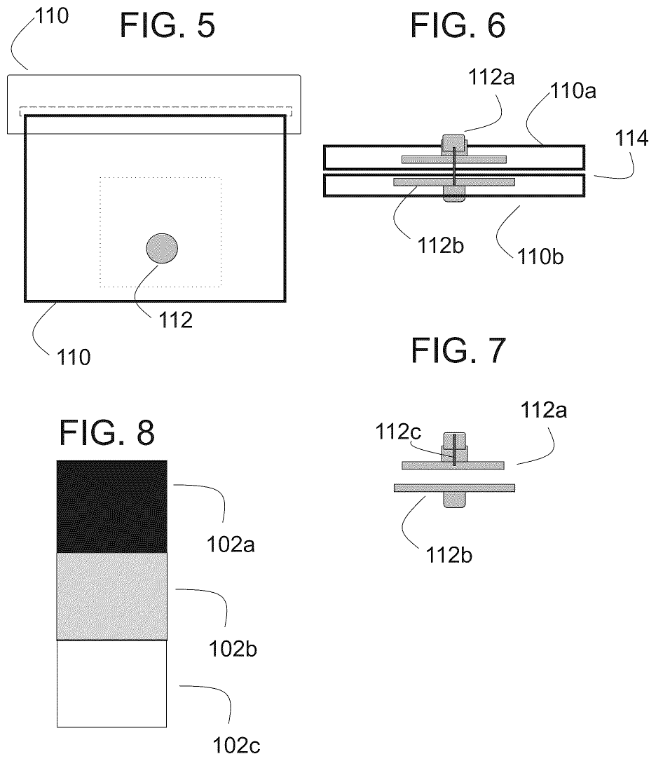

Extended fabric parts 110, integral to or attached to the molded frame 102 via glue or sewing, extend from the opening edges and serve as temporary holders for a retainer assembly 112. As best seen in FIGS. 5 and 6, the extended fabric parts 110 may include pockets, loops, or sleeves that are glued or sewn in place to releasably secure the retainer 112, allowing tool-free insertion and removal for maintenance or customization.

The retainer assembly 112, shown in detail in FIGS. 6 and 7, may comprise a tag-and-pin mechanism or similar structure. In one embodiment, the retainer assembly 112 includes a first component 112a and a second component 112b that cooperate to span across the chamber opening. The extended fabric parts 110a and 110b provide temporary holding points for the retainer components, as illustrated in FIG. 6.

The enclosure 100 maintains a semi-open configuration, where the retainer 112 spans across the chamber opening to prevent full device extraction while permitting partial access through gaps or apertures 114 for ports, buttons, or emergency interactions. This configuration is shown in FIGS. 1, 5, and 6.

Referring to FIG. 8, variable opacity is achieved via interchangeable molded frames. A clear molded frame 102c allows visual monitoring of the device screen (e.g., for medical monitoring or educational apps). A semi-opaque molded frame 102b, which may comprise frosted or translucent material, provides silhouette visibility while reducing visual distraction. A fully opaque molded frame 102a blocks all views for high-distraction environments. These interchangeable frames allow users to select the appropriate level of visibility for their specific needs. For example, clear molded frames provide limited usages for students with medical or educational needs.

To enhance extensibility, the enclosure 100 includes modular attachment points 118 on the molded frame 102 or fabric panels 110. These attachment points may comprise clips, slots, Velcro strips, magnetic interfaces, or other fastening mechanisms that allow addition of specialty components without permanent modification to the enclosure.

For example, as shown in FIG. 1, a signal-blocking material pouch 120 may be attached to the enclosure 100 via the modular attachment points 118. The signal-blocking pouch 120 may be embedded with Faraday mesh or similar RF shielding material for selectively blocking wireless signals like Wi-Fi or cellular data while permitting inserted cables for charging or sharing files or media.

Other add-on modules that may be added and integrated include modules for multi-device dividers for segmented storage within the chamber 108, eco-liners for sustainability, or AR-enabled attachments or stickers for app integration and usage tracking.

Additionally, as shown in FIGS. 1, 2, 3, and 4, the enclosure 100 may include dedicated holes or apertures 114 in the molded frame 102 or fabric panels 110 for charging access. These apertures 114 may be aligned with USB, Lightning, or other device ports, allowing users to connect charging cables without removing the device from the enclosure.

The apertures 114 may also provide access for limited interactions, such as accessing power buttons, volume controls, or headphone jacks, allowing users to perform basic functions without removing the device or compromising the retainer's barrier function.

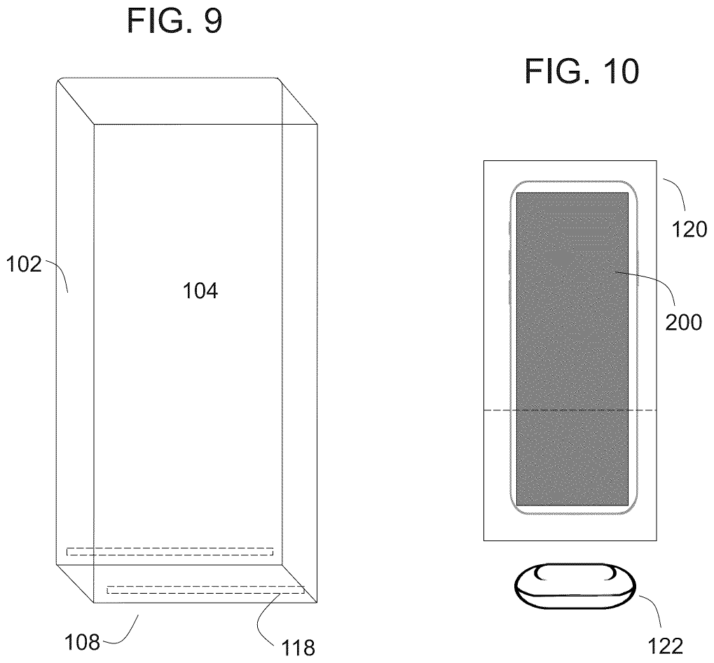

Referring to FIGS. 1 and 9, the chamber 108 is sized to hold at least one mobile device 200 (shown in outline in FIG. 1). However, the chamber 108 is configured with sufficient space to accommodate multiple items simultaneously, including one or more mobile devices, smartwatches 202, earbuds, or other electronic accessories.

Furthermore, the design accommodates configurations where a phone is wrapped in a signal-blocking pouch (such as an inner Faraday sleeve) and then placed within the chamber 108, providing enhanced shielding without restricting the enclosure's overall functionality. This dual-layer shielding approach combines the structural protection of the enclosure with selective RF blocking or other added functions.

In operation, a user inserts one or more devices into the chamber 108, optionally wrapping a device in a signal-blocking pouch 120 first. The user then positions the retainer assembly 112 within the extended fabric parts 110, which temporarily hold the retainer in place without requiring tools or permanent fastening.

The user may apply adhesive stickers to the molded surfaces 104 for personalization, institutional branding, or functional purposes such as adding barcodes or QR codes for tracking and management. Furthermore, the surface 104 also allow permanent engraving via laser or other means. As shown in FIG. 10, a customized graphic or logo 120 may be applied to the surface 104 of the enclosure.

The hybrid construction ensures the enclosure is lightweight yet robust, suitable for repeated use in educational settings where devices may be collected and redistributed daily. The smooth, non-porous molded plastic surfaces 104 can be easily wiped clean with disinfectant solutions or wipes between uses, addressing hygiene concerns in shared environments.

The variable opacity of the molded frame feature allows institutions to select the appropriate level of visibility for their needs. For example, clear frames 102c may be used in settings where school allows students limited for medical or educational needs, while fully opaque frames 102a may be preferred in high-distraction environments like testing situations.

The modular attachment points 118 provide flexibility for future enhancements. As new needs arise, such as additional tracking tags and compatible add-on modules can be developed and attached without requiring replacement of the core enclosure structure.

Variations of the invention include integrating passive signal-blocking mesh in molded for selective interference with wireless signals, scaling the chamber 108 for multi-device compartments with add-on dividers, or incorporating embedded RFID tags for automated tracking and management.

The best mode contemplated comprises a polycarbonate molded frame 102 with neoprene or vinyl fabric panels 110, variable opacity achieved through interchangeable molded frame sections (102a, 102b, 102c), extended fabric parts 110 attached via glue or sewing for temporarily holding a tag-and-pin retainer assembly 112, modular attachment points 118 for add-ons like module tags, precisely placed apertures 114 for charging and limited access, a chamber 108 sized for multiple devices with wrapped configurations, and cleanable molded surfaces 104 for hygiene.

In still further embodiments, the enclosure 100, its frame 102, panels 110, modular components, retainer structures 112, or any sub-assemblies may be formed from a wide variety of materials beyond those expressly described herein. Suitable alternative materials include, but are not limited to, metals (e.g., aluminum, steel, magnesium alloys), acrylic, polycarbonate blends, ABS, silicone, synthetic fabrics, thermoplastic elastomers (TPE), flexible elastomers, composite laminates, biodegradable or bio-based polymers, reinforced fiber materials, or any combination or layered configuration thereof.

Additional embodiments may incorporate alternative structural geometries; multi-part, foldable, or hinge-based architectures; interchangeable or reconfigurable frame sections; or variable-thickness regions designed to alter rigidity, impact resistance, or opacity.

Other embodiments may employ different closure or retention mechanisms, including but not limited to sliding locks, magnetic barriers, snap-fit components, tethered barriers, flexible strap systems, or any functional equivalent that restricts device removal while allowing partial access.

Further variations may include embedded or attachable electronic or sensing elements, such as RFID tags, proximity sensors, accelerometers, or compliance-tracking indicators. The enclosure may also support interchangeable or stackable modular extensions, enabling specialized functions such as additional shielding layers, privacy panels, thermal-dissipation modules, or expanded chambers for accessories.

Any of the embodiments disclosed herein may be implemented using alternate manufacturing methods, including molding, additive manufacturing, lamination, thermoforming, die-cutting, over-molding, or hybrid fabrication processes.

These various embodiments are intended to prevent unauthorized reverse engineering, to minimize compatibility with competing designs, and to avoid infringement while preserving the core inventive concepts described in the present disclosure. Accordingly, the embodiments described herein are illustrative rather than limiting, and numerous other configurations remain within the scope of the invention.

While the present invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A hybrid enclosure for mobile electronic devices, comprising:
more openings;
variation of molded frames with variable opacity selected from clear, semi-opaque, or opaque materials integrated into the enclosure;
vice interactions.

2. The hybrid enclosure of claim 1, wherein said variable opacity is achieved through interchangeable molded plastic frame.

3. The hybrid enclosure of claim 1, wherein said molded plastic frame has a smooth, non-porous surface configured for easy cleaning with disinfectant solutions or wipes to maintain hygiene in shared use.

4. The hybrid enclosure of claim 1, wherein said chamber accommodates a phone wrapped in a signal-blocking pouch for enhanced RF shielding within the enclosure.

5. The hybrid enclosure of claim 1, wherein said chamber is configured to hold multiple items simultaneously, including mobile devices, smartwatches, and earbuds.

6. The hybrid enclosure of claim 1, wherein said holes are aligned with device ports for charging cables or positioned for access to buttons like power or volume controls.

7. The hybrid enclosure of claim 1, wherein said add-on components include a signal-blocking material pouch embedded with Faraday mesh for selective RF shielding.

8. The hybrid enclosure of claim 1, wherein said molded plastic frame comprises polycarbonate, ABS, or silicone, and said extended fabric panels comprise neoprene, vinyl, nylon, polyester, or combinations thereof.

9. The hybrid enclosure of claim 1, wherein said extended fabric parts include pockets, loops, or sleeves formed by gluing or sewing fabric extensions to said fabric panels for releasable holding of said retainer assembly.

10. The hybrid enclosure of claim 1, wherein said retainer assembly comprises a tag-and-pin mechanism, rod, or barrier element that spans a chamber opening.

11. The hybrid enclosure of claim 2, wherein said variable opacity panels are interchangeable and include frosted material for semi-opaque visibility or solid material for full opacity.

12. The hybrid enclosure of claim 1, further comprising AR-scannable elements on said surface or panels for integration with mobile apps providing usage statistics.

13. A method of reducing distractions from mobile electronic devices in a controlled environment, the method comprising:
of contents while permitting partial access to device functions;
or permanently engraved designs to a surface of said molded plastic frame for customization;
tags with functions; and
arging said devices or limited interactions without removal.

14. The method of claim 13, wherein said inserting includes placing a phone wrapped in a signal-blocking pouch within said chamber for added shielding.

15. The method of claim 13, further comprising cleaning said molded plastic frame with disinfectant solutions or wipes between uses to maintain hygiene in shared environments.

16. The method of claim 13, wherein said temporarily securing is accomplished without tools by inserting said retainer assembly into pockets, loops, or sleeves formed in said extended fabric parts.

17. The method of claim 13, wherein said selecting and integrating includes replacing a molded plastic frame section with a different opacity level.

18. A customizable system for enclosing mobile electronic devices, comprising:
etainer configured to create a semi-open barrier that restricts content extraction but allows access to ports or buttons;

19. The customizable system of claim 18, wherein said molded plastic component has a non-porous surface facilitating cleaning with disinfectant solutions to address hygiene in educational or shared-use settings.

20. The customizable system of claim 18, wherein said apertures are strategically positioned to align with device charging ports and control buttons while maintaining said semi-open barrier function.
